(19) United States
(12) Patent Application Publication
(10) Pub. No.: US 2014/0216544 A1
(43) Pub. Date: Aug. 7, 2014

(54) ELECTRICALLY CONDUCTIVE ADHESIVE, SOLAR BATTERY MODULE USING THE SAME, AND PRODUCTION METHOD THEREOF

(71) Applicant: DEXERIALS CORPORATION, Tokyo (JP)

(72) Inventor: Koichi NAKAHARA, Tochigi (JP)

(73) Assignee: DEXERIALS CORPORATION, Tokyo (JP)

(21) Appl. No.: 14/244,960

(22) Filed: Apr. 4, 2014

Related U.S. Application Data
(63) Continuation of application No. PCT/JP2012/076354, filed on Oct. 11, 2012.

(30) Foreign Application Priority Data
Oct. 18, 2011 (JP) 2011-229074

(51) Int. Cl. H01L 31/05

(52) U.S. Cl. CPC H01L 31/0512
USPC 136/256; 156/327; 252/514

(57) ABSTRACT

To provide an electrically conductive adhesive, which contains: a curable resin; electrically conductive particles: a curing agent; and a black colorant consisting of titanium black, wherein the electrically conductive particles are silver-coated copper powder, and wherein the electrically conductive adhesive is configured to connect an electrode of a solar battery cell with tab wire.

### CROSS-REFERENCE TO RELATED APPLICATION

This application is a continuation application of International Application PCT/JP2012/076354 filed on Oct. 11, 2012 and designated the U.S., the entire contents of which are incorporated herein by reference.

### BACKGROUND OF THE INVENTION

1. Field of the Invention

The present invention relates an electrically conductive adhesive, a solar battery module using the electrically conductive adhesive, and a production method of the solar battery module.

2. Description of the Related Art

Solar batteries have been expected to be as a new energy source, as sun light, which is clean and is unlimitedly supplied, is directly transformed to electricity.

The solar batteries are used as a solar battery module, in which pluralities of solar battery cells are connected with tab wire.

As for conventional tab wire, a type of wire, which solder was coated on a surface of copper wire, has been used. However, high temperature is necessary to realize solder connection, and therefore a short circuit occurs due to the solder overflow (leaked) from the tab wire caused by cracking or warping of a panel of a light-receiving surface. This was a factor of causing a problem.

As for a connecting material replacing the solder, therefore, an adhesive, such as an electrically conductive adhesive, has been used. Examples of the tab wire coating with such an adhesive include tab wire, in which an entire surface of copper wire is coated with an electrically conductive adhesive. Such tab wire can connect at low temperature, problems that warping and cracking of a solar battery cell occur can be reduced.

Associated with the connection of the tab wire with the solar battery cell, whether or not the tab wire and the electrode of the solar battery cell are connected in an appropriate position (positioning) is confirmed by coloring the electrically conductive adhesive, which is a connecting material, and recognizing this color by a camera.

Examples of the electrically conductive adhesive used for the aforementioned connection include an electrically conductive adhesive containing carbon black (see, for example, Japanese Patent Application Laid-Open (JP-A) No. 2011-153214).

In the case where this electrically conductive adhesive is used, however, there are problems that adhesion and connection reliability are not sufficient, through recognition by cameras is excellent. Moreover, there is a problem that storage stability is not sufficient. Furthermore, there is a problem that generating efficiency is reduced due to overflow of the electrically conductive adhesive from the connection position.

As for an electrically conductive adhesive connecting between electrodes, an anisotropic conductive film configured to connect an electrode of a substrate with an electrode of an electronic component has been known, and inorganic filler is typically used for the anisotropic conductive film (see, for example, JP-A No. 2007-018760). Examples of the inorganic filler include silica, alumina, carbon, titanium black, titanium nitride, graphite powder, and iron black. The inorganic filler is added for improving recognition of positioning when an electrode of a substrate is connected with an electrode of an electronic component. However, a study for using the anisotropic conductive film using connection of a solar battery has not been conducted, and still more, whether or not the anisotropic conductive film adversely affect generating efficiency has not been studied at all.

Accordingly, there are currently needs for an electrically conductive adhesive, which is used for a solar battery module, has excellent recognition by cameras, adhesion, and connection reliability, has storage stability, and do not adversely affect electrically conductive adhesive, a solar battery module using the electrically conductive adhesive, and a production method of the solar battery module.

### SUMMARY OF THE INVENTION

The present invention aims to solve the aforementioned problems in the art, and to achieve the following object. Namely, an object of the present invention is to provide an electrically conductive adhesive, which is used for a solar battery module, has excellent recognition by cameras, adhesion, and connection reliability, has storage stability, and do not adversely affect generating efficiency, and to provide a solar battery module using the electrically conductive adhesive, and a production method of the solar battery module.

The means for solving the aforementioned problems are as follows:

<1> An electrically conductive adhesive, containing:

a curable resin;

electrically conductive particles;

a curing agent; and

a black colorant consisting of titanium black,

wherein the electrically conductive particles are silver-coated copper powder, and

wherein the electrically conductive adhesive is configured to connect an electrode of a solar battery cell with tab wire.

<2> The electrically conductive adhesive according to <1>, wherein an amount of the black colorant consisting of the titanium black is 0.1% by mass to 10.0% by mass relative to resins in the electrically conductive adhesive.
<3> The electrically conductive adhesive according to any of <1> or <2>, wherein an amount of the electrically conductive particles is 3% by mass to 10% by mass relative to resins contained in the electrically conductive adhesive.
<4> The electrically conductive adhesive according to any one of <1> to <3>, wherein the electrically conductive adhesive is in the form of a film, or a paste.
<5> A solar battery module, containing:

a solar battery cell containing an electrode;

tab wire; and

an adhesive layer formed of the electrically conductive adhesive according to any of <1> to <4>,

wherein the electrode of the solar battery cell is connected to the tab wire through the adhesive layer.

<6> A method for producing a solar battery module, containing:

arranging an adhesive layer formed of the electrically conductive adhesive according to any one of <1> to <4> and tab wire on an electrode of a solar battery cell that contains the electrode so that the electrode and the tab wire are bonded via the adhesive layer and are electrically connected as pressed and heated;

covering the solar battery cell with a sealing resin, and further covering the sealing resin with a moisture-proof backing sheet or a glass plate;

pressing either the moisture-proof backing sheet or the glass plate; and

heating a heating stage on which the solar battery cell is placed.

The present invention can solve the aforementioned various problems in the art, achieve the aforementioned object, and can provide an electrically conductive adhesive, which is used for a solar battery module, has excellent recognition by cameras, adhesion, and connection reliability, has storage stability, and do not adversely affect generating efficiency, as well as a solar battery module using the electrically conductive adhesive, and a production method of the solar battery module.

### BRIEF DESCRIPTION OF THE DRAWINGS

FIG. 1 is a schematic partial cross-sectional view illustrating one example of the solar battery module of the present invention.

FIG. 2 is a schematic cross-sectional view illustrating one example of a vacuum laminator before use.

FIG. 3A is an explanatory diagram of use of a vacuum laminator.

FIG. 3B is an explanatory diagram of use of a vacuum laminator.

FIG. 3C is an explanatory diagram of use of a vacuum laminator.

FIG. 3D is an explanatory diagram of use of a vacuum laminator.

FIG. 3E is an explanatory diagram of use of a vacuum laminator.

FIG. 4A is a schematic cross-sectional view for explaining an arranging step and a covering step.

FIG. 4B is a schematic cross-sectional view for explaining a pressing step and a heating step.

FIG. 4C is a schematic cross-sectional view illustrating one example of the solar battery module of the present invention.

### DETAILED DESCRIPTION OF THE INVENTION

### Electrically Conductive Adhesive

The electrically conductive adhesive of the present invention contains at least a curable resin, electrically conductive particles, a curing agent, and a black colorant consisting of titanium black, and may further contain other components according to the necessity.

The electrically conductive adhesive is configured to connect an electrode of a solar battery cell with tab wire.

### <Black Colorant>

The black colorant is composed of only titanium black. When the black colorant contains carbon black or another colorant, storage stability, generating efficiency, adhesion, and connection reliability may be degraded.

### —Titanium Black—

The titanium black is black titanium oxide, and is a black pigment having a structure where part of oxygen is removed from titanium dioxide. The titanium black is also called black low oxygen titanium.

The chromaticity (blackness) of the titanium black is appropriately selected depending on the intended purpose without any limitation, and for example, the L value in the Lab color space (Hunter Lab color space) is 20 or less.

The titanium black may be appropriately synthesized, or selected from commercial products. A synthesis method of the titanium black is appropriately selected depending on the intended purpose without any limitation, and examples thereof include a method disclosed in JP-A No. 05-193942. The commercial product of the titanium black is appropriately selected depending on the intended purpose without any limitation, and examples thereof include titanium black 12S (manufactured by Mitsubishi Materials Corporation, L value: 11.4), titanium black 13M (manufactured by Mitsubishi Materials Corporation, L value: 12.5), titanium black 13M-C (manufactured by Mitsubishi Materials Corporation, L value: 10.9), and Tilack D (manufactured by AKO KASEI CO., LTD., L value of a fine particle type: 13 to 15, L value of a ultrafine particle type: 14 to 18).

Although the titanium black of the commercial product is slightly tinted with blue, such titanium black can be also used as the titanium black in the present invention.

The average particle diameter of the titanium black is appropriately selected depending on the intended purpose without any limitation, but the average particle diameter thereof is preferably 10 nm to 200 nm, more preferably 20 nm to 150 nm, and even more preferably 50 nm to 100 nm. When the average particle diameter thereof is smaller than 10 nm, it may be difficult to handle such titanium black. When the average particle diameter thereof is greater than 200 nm, such titanium black may lack in the blackness (chromaticity). The titanium black having the average particle diameter in the aforementioned even more preferable range is advantageous in view of recognition by cameras.

The average particle diameter can be measured, for example, by a particle size distribution analyzer (Micro Track MT3100, manufactured by NIKKISO CO., LTD.).

An amount of the black colorant consisting of the titanium black is appropriately selected depending on the intended purpose without any limitation, and the amount thereof is preferably 0.1% by mass to 10.0% by mass, more preferably 0.3% by mass to 10.0% by mass, and even more preferably 0.4% by mass to 7.0% by mass relative to resins in the electrically conductive adhesive. When the amount thereof is smaller than 0.1% by mass, recognition thereof by cameras may be low. When the amount thereof is greater than 10.0% by mass, connection reliability of a resulting electrically conductive adhesive may be low. When the amount thereof is within the aforementioned even more preferable range, it is advantageous as storage stability, recognition by cameras, prevention in reduction of generating efficiency, adhesion, and connection reliability of a resulting electrically conductive adhesive are extremely excellent.

Examples of the resins in the electrically conductive adhesive include the curable resin, the curing agent, a film forming resin, and various rubbers.

### <Electrically Conductive Particles>

The electrically conductive particles are appropriately selected depending on the intended purpose without any limitation, provided that they are particles that are electrically conductive. Examples thereof include gold powder, silver powder, copper powder, nickel powder, gold-coated copper powder, and silver-coated copper powder.

Among them, silver-coated copper powder is preferable in view of prevention of corrosion.

### —Silver-Coated Copper Powder—

The silver-coated copper powder is copper powder at least part of surfaces of which are covered with silver. Use of the silver-coated copper powder can achieve an electrically conductive adhesive, which has excellent connection reliability, and does not reduce its generating efficiency.

In other words, the silver-coated copper powder is copper powder at least part of surfaces of which are coated with silver. The silver-coated copper powder may be copper powder entire surfaces of which are coated with silver, or copper powder part of surfaces of which are coated with silver. In the case where part of surfaces of the copper powder is coated with silver, the entire surfaces of the copper powder is preferably coated with silver without distributed unevenly, while exposing parts of the surfaces of the copper particle, rather than the silver is unevenly distributed to part of the surfaces of the copper powder. A silver-coated copper powder having uniform electric conductivity can be attained by coating the copper powder with silver without unevenly distributed. In this case, the coated silver is deposited on the surfaces of the copper in the form of dots, or a mesh.

Particle diameters of the copper powder are appropriately selected depending on the intended purpose without any limitation.

The silver-coated copper powder may be covered with fatty acid. Surfaces of the silver-coated copper powder can be made smooth by covering the silver-coated copper powder with the fatty acid. The fatty acid is appropriately selected depending on the intended purpose without any limitation, and examples thereof include stearic acid.

A production method of the silver-coated copper powder is appropriately selected depending on the intended purpose without any limitation, and examples thereof include the following methods [1] to [5].

[1] A method for precipitating metal silver on surfaces of metal copper powder using a silver complex salt solution containing silver nitrate, ammonium carbonate, and trisodium ethylene diamine tetraacetate (EDTA) (see, for example, JP-B No. 57-59283).
[2] A method for precipitating metal silver on surfaces of metal copper powder using a silver complex salt solution containing silver nitrate, ammonia water, and EDTA (see for example, JP-A No. 61-3802).
[3] A method, in which after a copper powder is dispersed in a chelating agent solution, a silver ion solution is added to the dispersion liquid to accelerate a reduction reaction, and a reducing agent is further added to completely precipitate by reduction, to thereby precipitate a silver coating on each surface of the copper powder (see, for example, JP-A No. 01-119602).
[4] A method for covering surfaces of copper powder with silver by a substitution reaction of silver ions and metal copper, performed in a solution containing an organic solvent, in which silver ions are present (see, for example, JP-A No. 2006-161081).
[5] A method containing subjecting copper powder, which has been processed to be flakes, to a heat treatment to oxidize surfaces of the copper powder, removing organic matter on the surfaces of copper powder in an alkaline solution and washing with water, acid washing the oxide on the surfaces of the copper powder in an acid solution and washing with water, adding a reducing agent to the acid solution in which the copper powder is dispersed to adjust pH, to thereby produce copper powder slurry, and continuously adding a silver ion solution to the copper powder slurry, to thereby form a silver layer on each surface of the copper powder through electroless substitution plating and reduction electroless plating (see, for example, JP-A No. 2010-174311).

Among them, the method of [5] is preferable.

The average particle diameter of the electrically conductive particles is appropriately selected depending on the intended purpose without any limitation, but the average particle diameter thereof is preferably 1 μm to 50 μm, more preferably 3 μm to 30 μm, and even more preferably 5 μm to 20 μm. When the average particle diameter is smaller than 1 μm, reliability may be low. When the average particle diameter is greater than 50 μm, a resulting solar battery cell may be damaged with the electrically conductive particles. The electrically conductive particles having the aforementioned even more preferable range of the average particle diameter is advantageous in view of long-term reliability.

The average particle diameter can be measured, for example, by a particle size distribution analyzer (Micro Track MT3100, manufactured by NIKKISO CO., LTD.).

An amount of the electrically conductive particles is appropriately selected depending on the intended purpose without any limitation, but the amount thereof is preferably 1% by mass to 20% by mass, more preferably 3% by mass to 10% by mass, and even more preferably 4% by mass to 6% by mass relative to resins in the electrically conductive adhesive. When the amount thereof is smaller than 1% by mass, connection reliability of a resulting electrically conductive adhesive may be low. When the amount thereof is greater than 20% by mass, connection reliability of a resulting electrically conductive adhesive may be low. When the amount thereof is within the aforementioned even more preferable range, it is advantageous as storage stability, recognition by cameras, prevention in reduction of generating efficiency, adhesion, and connection reliability of a resulting electrically conductive adhesive are all extremely excellent.

Examples of the resins in the electrically conductive adhesive include the curable resin, the curing agent, a film forming resin, and various rubbers.

### <Curable Resin>

The curable resin is appropriately selected depending on the intended purpose without any limitation, and examples thereof include an epoxy resin, and an acrylate resin.

### —Epoxy Resin—

The epoxy resin is appropriately selected depending on the intended purpose without any limitation, and examples thereof include a naphthalene-based epoxy resin, a biphenyl-based epoxy resin, a phenol novolak-based epoxy resin, a bisphenol-based epoxy resin (e.g., a bisphenol A-based epoxy resin, and a bisphenol F-based epoxy resin), a stilbene-based epoxy resin, a triphenol methane-based epoxy resin, a phenol aralkyl-based epoxy resin, a naphthol-based epoxy resin, a dicyclopethadiene-based epoxy resin, and a triphenylmethane-based epoxy resin. These may be used alone, or in combination.

### —Acrylate Resin—

The acrylate resin is appropriately selected depending on the intended purpose without any limitation, and examples thereof include methyl acrylate, ethyl acrylate, isopropyl acrylate, isobutyl acrylate, epoxy acrylate, ethylene glycol diacrylate, diethylene glycol diacrylate, trimethylol propane trimethylol propane triacrylate, dim ethyloltricyclodecane diacrylate, tetramethylene glycol tetraacrylate, 2-hydroxy-1,3-diacryloxypropane, 2,2-bis[4-(acryloxymethoxy)phenyl]propane, 2,2-bis[4-(acryloxyethoxy)phenyl]propane, dicyclopentenyl acrylate, tricyclodecanyl acrylate, tris(acryloxyethyl)isocyanurate, and urethane acrylate. These may be used alone, or in combination.

Examples of the acrylate resin further include inethacrylates of the above-listed acrylates.

These may be used alone, or in combination.

An amount of the curable resin is appropriately selected depending on the intended purpose without any limitation.

### <Curing Agent>

The curing agent is appropriately selected depending on the intended purpose without any limitation, and examples thereof include: imidazole, such as 2-ethyl-4-methylimidazole; organic peroxide, such as lauroyl peroxide, butyl peroxide, benzyl peroxide, dilauroyl peroxide, dibutyl peroxide, peroxydicarbonate, and benzoyl peroxide; an anionic curing agent, such as organic amine; and a cationic curing agent, such as a sulfonium salt, an onium salt, and an aluminum chelating agent.

Among them, particularly preferred are a combination of an epoxy resin and an imidazole-based latent curing agent, and a combination of an acrylate resin and an organic peroxide-based curing agent.

An amount of the curing agent is appropriately selected depending on the intended purpose without any limitation.

### <Other Components>

Other components are appropriately selected depending on the intended purpose without any limitation, and examples thereof include a film forming resin, a silane coupling agent, various rubbers, filler, a softening agent, an accelerator, an antioxidant, an organic solvent, and an ion catcher agent. An amount of the aforementioned other components is appropriately selected depending on the intended purpose without any limitation.

### —Film Forming Resin—

The film forming resin is appropriately selected depending on the intended purpose without any limitation, and examples thereof include a phenoxy resin, an unsaturated polyester resin, a saturated polyester resin, a urethane resin, a butadiene resin, a polyimide resin, a polyamide resin, and a polyolefin resin. These may be used alone, or in combination. Among them, a phenoxy resin is particularly preferable.

An amount of the film forming resin is appropriately selected depending on the intended purpose without any limitation.

A form of the electrically conductive adhesive is appropriately selected depending on the intended purpose without any limitation, and the electrically conductive adhesive may be in the form of a film, or a paste. The paste form means a semi-solid state having a slight viscosity, but not in the state where it is low viscous and has high fluidity, such as water, and an organic solvent.

### (Solar Battery Module)

The solar battery module of the present invention contains at least a solar battery cell, tab wire, and an adhesive layer, and may further contain other components, such as sealing resin, moisture-proof backing sheet, and a glass plate, according to the necessity.

The electrode of the solar battery cell and the tab wire are connected through the adhesive layer.

### <Solar Battery Cell>

The solar battery cell is appropriately selected depending on the intended purpose without any limitation, provided that the solar battery cell contains a photoelectric conversion element serving as a photoelectric conversion unit, and an electrode. Examples thereof include a thin film solar battery cell, and a crystalline solar battery cell.

The thin film solar battery cell is appropriately selected depending on the intended purpose without any limitation, and examples thereof include an amorphous silicon solar battery cell, a CdS/CdTe solar battery cell, a dye-sensitized solar battery cell, an organic thin film solar battery cell, and a microcrystalline solar battery cell (a tandem solar battery cell).

The average thickness of the solar battery cell is appropriately selected depending on the intended purpose without any limitation.

### —Electrode—

The electrode is appropriately selected depending on the intended purpose without any limitation.

### <Tab Wire>

The tab wire is appropriately selected depending on the intended purpose without any limitation, provided that it is wire configured to electrically connect between the solar battery cells adjacent to each other.

A material of the tab wire is appropriately selected depending on the intended purpose without any limitation, and examples thereof include copper, aluminum, iron, gold, silver, nickel, palladium, chromium, molybdenum, and an alloy thereof. Moreover, these metals may be optionally gold-plated, silver-plated, tin-plated, or solder-plated.

A shape of the tab wire is appropriately selected depending on the intended purpose without any limitation, and examples thereof include a ribbon base.

The average width of the tab wire is appropriately selected depending on the intended purpose without any limitation, but the average width thereof is preferably 1 mm to 6 mm.

The average thickness of the tab wire is appropriately selected depending on the intended purpose without any limitation, but the average thickness thereof is preferably 5 μm to 300 μm.

### <Adhesive Layer>

The adhesive layer is formed of the electrically conductive adhesive of the present invention.

A method for forming the adhesive layer is appropriately selected depending on the intended purpose without any limitation, and examples thereof include: a method, in which the electrically conductive adhesive in the form of a film is laminated on the tab wire; and a method, in which the electrically conductive adhesive in the firm of a paste is applied onto the tab wire by coating.

The tab wire, in which the adhesive layer has been formed, may be attained by laminating the electrically conductive adhesive in the form of a film on a wide material (e.g., a copper foil) that will be tab wire, to thereby prepare a laminate, and slitting the laminate in the width of tab wire.

The coating method of the adhesive is appropriately selected depending on the intended purpose without any limitation, and examples thereof include spin coating, casting, microgravure coating, gravure coating, knife coating, bar coating, roll coating, wire bar coating, dip coating, and spray coating.

The average thickness of the adhesive layer is appropriately selected depending on the intended purpose without any limitation, but the average thickness thereof is preferably 3 μm to 100 μm, more preferably 5 μm to 30 μm, and even more preferably 8 μm to 25 μm. When the average thickness thereof is less than 3 μm, adhesion strength may be significantly reduced. When the average thickness thereof is greater than 100 μm, a resulting adhesive layer extends over the tab wire, and a problem in electrical connection may be caused. When the average thickness thereof is within the aforementioned even more preferable range, it is advantageous in view of adhesion reliability.

Here, the average thickness of an average value of values measured at randam 5 positions per 20 cm².

The average width of the adhesive layer is appropriately selected depending on the intended purpose without any limitation, but the average width thereof is preferably 1 mm to 6 mm, and identical to or smaller than the width of the tab wire.

### <Sealing Resin>

The sealing resin is appropriately selected depending on the intended purpose without any limitation, and examples thereof include an ethylene-vinyl acetate copolymer (EVA), ethylene/vinyl acetate/triallylisocyanurate (EVAT), polyvinyl butyrate (PVB), polyisobutylene (PIB), a silicone resin, and a polyurethane resin.

### <Moisture-Proof Backing Sheet>

The moisture-proof backing sheet is appropriately selected depending on the intended purpose without any limitation, and examples thereof include polyethylene terephthalate (PET), aluminum (Al), and a laminate containing PET, Al, and polyethylene (PE).

### <Glass Plate>

The glass plate is appropriately selected depending on the intended purpose without any limitation, and examples thereof include a soda lime float glass plate.

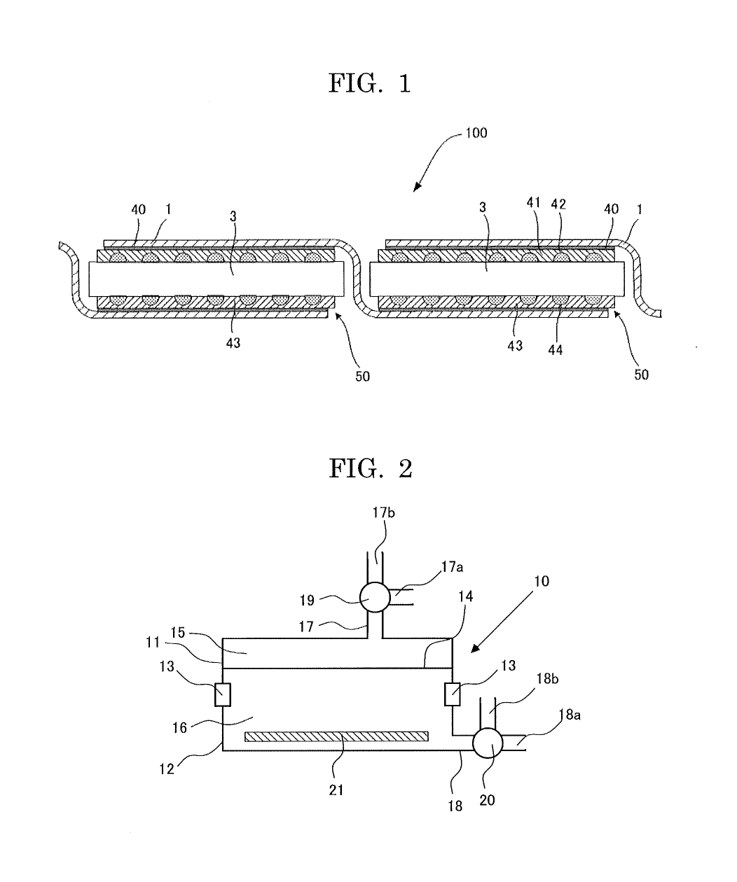

A structure of the solar battery module is appropriately selected depending on the intended purpose without any limitation, and examples thereof include a structure where a plurality of the solar battery cells are tandemly electrically connected with the tab wire. One example of the structure of the solar battery module of the present invention is explained with reference of a drawing. FIG. 1 is a schematic partial cross-sectional view illustrating one example of the solar battery module of the present invention. The solar battery module 100 of FIG. 1 is a module, in which a plurality of solar battery cells 50 are tandemly electrically connected with the tab wire 1 functioning as an inter connector. The solar battery cell 50 contains a photoelectric conversion element 3, a first electrode 41, which is a bus bar electrode provided on a light-receiving surface thereof, a second electrode 43, which is a bus bar electrode provided on a surface that does not receive light, and finger electrodes 42 and 44, which are collector electrodes provided so that they are substantially perpendicular to the first electrode 41 and the second electrode 43 above the photoelectric conversion element 3. On certain positions on both surfaces of the tab wire 1, an adhesive layer 40 is formed. The tab wire 1 electrically connects first electrode 41 of one solar battery cell 50 with the second electrode 43 of adjacent another solar battery cell 50 using the both surfaces of the tab wire 1.

A production method of the solar battery module is appropriately selected depending on the intended purpose without any limitation, but it is preferably the method for producing a solar battery module according to the present invention, which is described below.

### (Method for Producing Solar Battery Module)

The method for producing solar battery module according to the present invention contains at least an arranging step, a covering step, a pressing step, and a heating step, and may further contain other steps according to the necessity.

The method for producing a solar battery module according to the present invention can be suitably used for production of the solar battery module of the present invention.

The method for producing a solar battery module is preferably carried out using a vacuum laminator.

### <Arranging Step>

The arranging step is appropriately selected depending on the intended purpose without any limitation, provided that it contains arranging an adhesive layer formed of the electrically conductive adhesive of the present invention and tab wire on an electrode of a solar battery cell that contains the electrode therein so that the electrode and the tab wire are bonded via the adhesive layer and are electrically connected as pressed and heated.

In the arranging step, after forming the adhesive layer formed of the electrically conductive adhesive on the tab wire in advance, the tab wire, on which the adhesive layer has been formed, may be arranged in an intended position of the electrode of the solar battery cell. Alternatively, after forming the electrically conductive adhesive layer on the electrode of the solar battery cell in advance, the tab wire may be arranged in an intended position of the electrode of the solar battery cell.

The solar battery cell is appropriately selected depending on the intended purpose without any limitation, and examples thereof include the solar battery cell listed in the descriptions of the solar battery module of the present invention.

### <Covering Step>

The covering step is appropriately selected depending on the intended purpose without any limitation, provided that it contains covering the solar battery cell with a sealing resin, and further covering the sealing resin with a moisture-proof backing sheet or a glass plate.

The sealing resin, moisture-proof backing sheet, and glass plate are appropriately selected depending on the intended purpose without any limitation, and examples thereof include the sealing resin, the moisture-proof backing sheet, and the glass plate listed in the descriptions of the solar battery module of the present invention.

### <Pressing Step>

The pressing step is appropriately selected depending on the intended purpose without any limitation, provided that it contains pressing either the moisture-proof backing sheet or the glass plate.

The pressure for pressing either the moisture-proof backing sheet or the glass plate is appropriately selected depending on the intended purpose without any limitation.

The duration for pressing either the moisture-proof backing sheet or the glass plate is appropriately selected depending on the intended purpose without any limitation.

### <Heating Step>

The heating step is appropriately selected depending on the intended purpose without any limitation, provided that it contains heating a heating stage on which the solar battery cell is placed.

The adhesive layer and the sealing resin can be heated by heating the heating stage.

The heating temperature in the heating step is appropriately selected depending on the intended purpose without any limitation, but the heating temperature is preferably 50° C. to 250° C., more preferably 100° C. to 200° C., and even more preferably 120° C. to 170° C. When the heating temperature is lower than 50° C., adhesion between the electrode and the tab wire, and sealing may be insufficient. When the heating temperature is higher than 250° C., an organic resin, such as the adhesive layer, and the sealing resin may cause thermal decomposition. When the heating temperature is within the aforementioned even more preferable range, it is advantageous in view of reliability in both adhesion and connection.

The heating duration in the heating step is appropriately selected depending on the intended purpose without any limitation, but the heating duration is preferably 1 second to 1 hour, more preferably 5 seconds to 30 minutes, and even more preferably 10 seconds to 20 minutes. When the heating duration is shorter than 1 second, adhesion between the electrode and the tab wire, and sealing may be insufficient. When the heating duration is over 1 hour, adhesion strength may be reduced. When the heating duration is within the aforementioned even more preferable range, it is advantageous in view of reliability in both adhesion and connection.

An order for performing the pressing step, and the heating step is appropriately selected depending on the intended purpose without any limitation. The heating stage may be heated before starting the pressing step. The heating stage may be heated after starting the pressing step.

### <Vacuum Laminator>

The vacuum laminator contains at least a first chamber, a second chamber, a flexible sheet, and a heating stage, and may further contain other members, according to the necessity.

The first chamber and the second chamber are sectioned with the flexible sheet.

Internal pressures of the first chamber and the second chamber can be each independently controlled.

The heating stage can be heated, and is provided inside the second chamber.

The vacuum laminator and the operation thereof are explained with reference to drawings. FIG. 2 is a schematic cross-sectional view illustrating one example of the vacuum laminator before use. The vacuum laminator 10 is composed of an upper unit 11 and a lower unit 12. These units are detachably integrated via a sealing member 13. To the upper unit 11, a flexible sheet 14 is provided, and the flexible sheet 14 sections the vacuum laminator 10 into a first chamber 15 and a second chamber 16.

Moreover, pipes 17, 18 are respectively provided to the upper unit 11 and the lower unit 12 so that the internal pressure of each unit can be independently adjusted. The pipe 17 is branched into two directions, a pipe 17a and a pipe 17b, with a switching valve 19, and the pipe 18 is branched into two directions, pipe 18a and a pipe 18b, with a switching valve 20. Moreover, a heating stage 21, which is capable of heating, is provided to the lower unit 12.

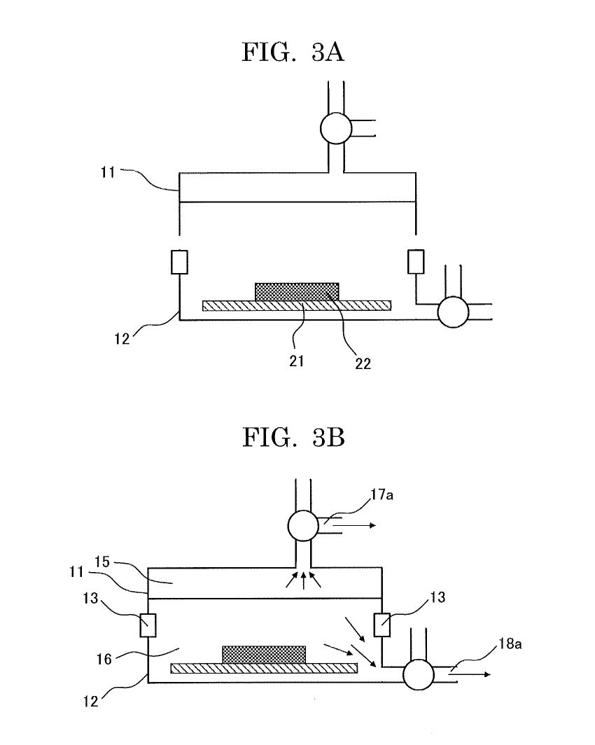

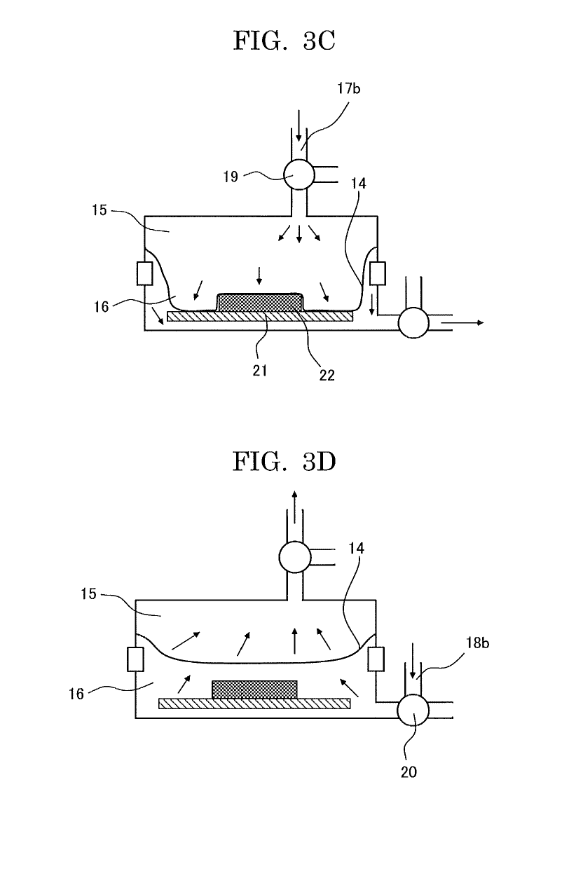

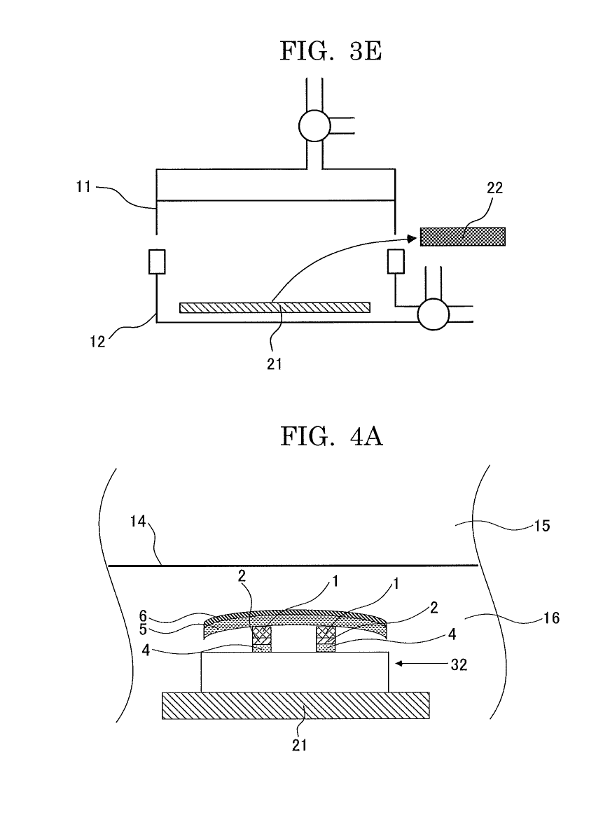

Such a vacuum laminator 10 can be used, for example, in a manner illustrated in FIGS. 3A to 3E.

First, a laminate 22, which is to be thermally laminated, is placed on a heating stage 21, as illustrated in FIG. 3A.

Next, as illustrated in FIG. 3B, an upper unit 11 and a lower unit 12 are detachably integrated via a sealing member 13, and then a pipe 17a and a pipe 18a are each connected to a vacuum pump (not illustrated) to turn the internal atmosphere of the first chamber 15 and the second chamber 16 into high vacuum.

Nest, a switching valve 19 is switched to introduce air to the first chamber 15 from the pipe 17b, while maintaining the internal atmosphere of the second chamber 16 high vacuum, as illustrated in FIG. 3C. During this operation, a heating stage 21 is heated. As a result, the laminate 22 is pressed with a flexible sheet 14 while being heated by the heating stage 21.

Next, a switching valve 20 is switched to introduce air to the second chamber from the pipe 18b to make the internal pressure of the first chamber 15 and the second chamber 16 identical, as illustrated in FIG. 3D.

Finally, the upper unit 11 and the lower unit 12 are separated and the laminate 22, which has been subjected to a thermal laminate treatment, is taken out from the heating stage 21, as illustrated in FIG. 3E. As a result, the operation cycle of the vacuum laminator 10 is completed.

Note that, the obtained laminate 22 is the solar battery module of the present invention in the method for producing a solar battery module.

The connection between tab wire and an electrode, and sealing with a sealing resin can be collectively performed by carrying out the operations illustrated in FIGS. 3A to 3E.

One example of the vacuum laminator is explained above, but the vacuum laminator is not limited to the vacuum laminator composed of the upper unit and the lower unit as illustrated in FIG. 2. A vacuum laminator having a structure where an internal area of one housing into divided into 2 chambers, and placing and collecting of a laminate is carried out by opening and closing a door can be also used. Moreover, the first chamber and the second chamber may be compressed to the pressure equal to or greater than atmospheric pressure by introducing compressed air. Moreover, the second chamber may be designed to merely discharge air inside the chamber without vacuuming the second chamber.

Next, one example of the method for producing a solar battery module according to the present invention using the vacuum laminator is specifically explained with reference to drawings.

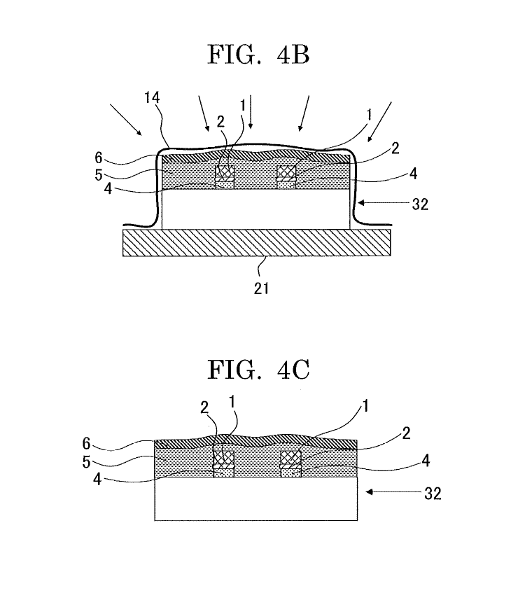

FIG. 4A is a schematic cross-sectional view (a partial enlarged view of the vacuum laminator) for explaining the arranging step and the covering step. FIG. 4B is a schematic cross-sectional view for explaining the pressing step and the heating step. FIG. 4C is a schematic cross-sectional view illustrating one example of the solar battery module of the present invention.

As illustrated in FIG. 4A, a solar battery cell 32, in which electrodes 4 are formed, is placed on a heating stage 21 of a second chamber 16, which is sectioned from a first chamber 15 with a flexible sheet 14. Subsequently, an adhesive layer 2 and tab wire 1 are placed on the electrodes 4 so that the electrodes 4 and the tab wire 1 are bonded and electrically connected via the adhesive layer 2 as pressed and heated. Subsequently, a sealing resin 5 and a moisture-proof backing sheet 6 are sequentially arranged to cover the solar battery cell 32.

Subsequently, the internal pressure of the first chamber 15 and the second chamber 16 are turned to a vacuum state, followed by returning the internal pressure of the first chamber 15 to atmospheric pressure while maintaining the vacuum state of the second chamber 16, to press the mixture-proof backing sheet 6 with the flexible sheet 14, and heating the solar battery cell 32 through heating the heating stage 21, as illustrated in FIG. 4B. As a result, the electrodes 4 of the solar battery cell 32 and the tab wire 1 are bonded with the adhesive layer 2 and are electrically connected, and the solar battery cell 32 is sealed with the sealing resin. In this manner, a solar battery module is obtained (FIG. 4C).

By carrying out the operations illustrated in FIGS. 4A to 4C, laminate collective pressure bonding, which include bonding and electrically connecting the electrodes 4 and the tab wire 1, and sealing the solar battery cell 32 with the sealing resin, can be performed.

### EXAMPLES

Examples of the present invention are explained hereinafter, but these examples shall not be construed as to limit the scope of the present invention.

### Production Example 1

### Production of Silver-Coated Copper Powder

As for copper powder, used was copper powder obtained by mechanically pulverizing atomized copper powder obtained through a method called atomizing. Note that, it was assumed that fatty acid was added during the mechanical stirring for the purpose of preventing aggregation of copper powder to produce coarse particles. Specifically, flake copper powder (AFS-Cu 7 μm) manufactured by NIPPON ATOMIZED METAL POWDERS CORPORATION was used. This copper powder had the weight mean particle diameter D₅₀ of 7.9 μm as measured through laser diffraction scattering particle size distribution analysis.

The flaked copper powder (500 g) was subjected to a heat treatment (oxidization treatment) in the air at 250° C., for 5 minutes. Thereafter, the copper powder, which had been subjected to the oxidization treatment, was added in a mortar and roughly crushed. The resulting copper powder (500 g) was added to 1,000 mL of a 1% by mass potassium hydroxide aqueous solution, and the mixture was stirred for 20 minutes, followed by carrying out first decantation. To the resultant, 1,000 mL of pure water was further added, and the resulting mixture was stirred for a few minutes.

Thereafter, second decantation was carried out. To the resultant, 2,500 mL of a sulfuric acid aqueous solution having a sulfuric acid concentration of 15 g/L was added, and the resultant was stirred for 30 minutes (acid cleaning). Further, acid cleaning with the sulfuric acid aqueous solution was repeated once more. Then, third decantation was carried out, and 2,500 mL of pure water was added to the resultant, followed by stirring for a few minutes. Then, fourth decantation was carried out, followed by filtration washing, and vacuum dehydration, to thereby separate the flaked copper powder from the solution. The resulting flaked copper powder was dried at 90° C. for 2 hours.

Subsequently, 2,500 mL of a sulfuric acid aqueous solution having a sulfuric acid concentration of 7.5 g/L was added to the dried flaked copper powder, and the mixture was stirred for 30 minutes. Then, fifth decantation was carried out. To the resultant, 2,500 mL of pure water was added, and the resultant was stirred for a few minutes.

Further, sixth decantation was carried out. To the resultant, 2,500 mL of a 1% by mass potassium sodium tartrate aqueous solution was added, and the resulting mixture was stirred for a few minutes, to thereby form copper slurry. To the copper slurry, dilute sulfuric acid or a potassium hydroxide aqueous solution was added, to thereby adjust pH of the copper slurry to the range of 3.5 to 4.5.

A substitution reaction, and a reduction reaction were carried out while 1,000 mL of a silver nitrate ammonium solution (obtained by adding 87.5 g of solver nitrate to water, and adding ammonia water to adjust the volume thereof to 1,000 mL) was gradually added to the copper slurry the pH of which had been adjusted over 30 minutes. The resultant was stirred for 30 minutes, to thereby obtain silver-coated copper powder.

Thereafter, seventh decantation was carried out. To the resultant, 3,500 mL of pure water was added, and the mixture was stirred for a few minutes. Next, eighth decantation was carried out. To the resultant, 3,500 mL of pure water was added, and the mixture was stirred for a few minutes. Thereafter, filtration washing, and vacuum dehydration were carried out to thereby separate the silver-coated copper powder from the solution. The resulting silver-coated copper powder was dried at 90° C. for 2 hours.

The obtained silver-coated copper powder (500 g) was placed in a tube-shaped furnace, and was subjected to a heat treatment in reducing atmosphere with a nitrogen flow (3.0 L/min to 3.5 L/min) at 200° C. for 30 minutes. The heat-treated silver-coated copper powder was crushed in a mortar. Then, the crushed silver-coated copper powder (500 g) was dispersed in 1,000 mL of a 0.5% by mass stearic acid isopropyl alcohol solution, and the mixture was stirred for 30 minutes.

The resultant was then subjected to filtration washing, and vacuum dehydration to thereby separate the silver-coated copper powder, which had been subjected to the heat treatment, and the stearic acid treatment, from the solution. The resulting silver-coated copper powder was dried at 90° C. for 2 hours, to thereby obtain the silver-coated copper powder, which had been subjected to the stearic acid treatment (see JP-A No. 2010-174311).

### Example 1

### Production of Solar Battery Module

### —Production of Electrically Conductive Adhesive Film—

An electrically conductive adhesive composition was prepared by mixing 25 parts by mass of a phenoxy resin (PKHH, manufactured by InChem), 45 parts by mass of an acrylate resin (NK ester A-IB, manufactured by Shin-Nakamura Chemical Co., Ltd.), 10 parts by mass of acrylic rubber (Teisan Resin SGP3, manufactured by Nagase ChemteX Corporation), 15 parts by mass of an isoprene-styrene copolymer (Septon 1001, manufactured by KURARAY CO., LTD.), 5 parts by mass of a curing agent (Nyper BW, manufactured by NOF Corporation, organic peroxide), 5 parts by mass of electrically conductive particles (the silver-coated copper powder obtained in Production Example 1, average particle diameter: 10 μm), and 0.1 parts by mass of Titanium Black 1 (13MT, manufactured by Mitsubishi Materials Corporation, average particle diameter: 80 nm).

Next, the obtained electrically conductive adhesive composition was applied on a polyethylene terephthalate film (release film) having a thickness of 50 μm, a surface of which had been subjected to a releasing treatment. The resultant was subjected to a heat treatment in an oven of 80° C. for 5 minutes to form a film. As a result, an electrically conductive adhesive film having the average thickness of 22 μm was obtained.

### —Laminating and Slitting—

The electrically conductive adhesive film was laminated on a copper foil, to thereby produce the copper foil on which the electrically conductive adhesive film had been laminated. Subsequently, the copper foil, on which the electrically conductive adhesive film had been laminated, was slit into a width of 4 mm, to thereby produce tab wire with an adhesive layer.

### —Production of Solar Battery Module—

A solar battery module was produced by laminate collective pressure bonding in accordance with the method illustrated in FIGS. 4A to 4C, using the vacuum laminator illustrated in FIG. 2.

As for a solar battery cell, a solar battery cell on which an electrode (white) 4 had been formed (Q6LTT-200, manufactured by Q-Cells, crystalline solar battery cell) was used.

As for conditions for temporarily bonding the tab wire with the adhesive layer produced in Example 1 (corresponding to the electrically conductive adhesive layer 2, and the tab wire 1 in FIG. 4A) on the electrode 4, the heating temperature was 70° C., the pressure was 0.5 MPa, and the duration was 1 second.

As for a sealing resin, an ethylene-vinyl acetate copolymer having a thickness of 500 μm was used.

As for a moisture-proof backing sheet, polyethylene terephthalate (BS-SP, manufactured by TOPPAN PRINTING CO., LTD.) having a thickness of 250 μm was used.

As for the conditions of heating and pressing, the pressure was 2 MPa, the heating temperature was 180° C., and the duration was 15 seconds.

### <Evaluations>

The electrically conductive adhesive film and solar battery module obtained in the aforementioned manner were subjected to the following evaluations. The results are presented in Table 1.

### —Storage Stability of Film—

The electrically conductive adhesive film with the release film was slit into a width of 4 mm. The slit was then coiled in the form of a reel by 100 m, and the obtained reel was stored at 25° C., 50% RH. The electrically conductive adhesive film was subjected to the measurements of a calorific value as measured by differential scanning calorimetry (DSC), a melt viscosity, and the below-mentioned connection reliability at the initial stage of the storage, and every month from the end of the storage. The maximum storage period the measurement result of which was not changed from the result of the initial stage of the storage was determined as a storable period, and was evaluated based on the following evaluation criteria.

### [Evaluation Criteria]

A: A storable period was 1 year or longer.
B: A storable period was 6 months or longer but shorter than 1 year.
C: A storable period was 4 months or longer but shorter than 6 months.
D: A storable period was shorter than 4 months.

### —Recognition by Cameras—

Whether or not the electrically conductive adhesive layer (black) was appropriately bonded on a white electrode of the solar battery module was determined by means of a 2,000,000-pixel digital monochrome camera for model FN (product name: Model FZ-S2M, manufactured by OMRON Corporation) as a visual recognition device. Specifically, 100 connection positions were measured by means of the camera, which was set to recognize white and black at certain threshold to measure a ratio (recognition rate (%)) of a judgment that the black electrically conductive adhesive layer was appropriately bonded to the white electrode. The results were evaluated based on the following evaluation criteria.

### [Evaluation Criteria]

A: The recognition rate was 95% or greater.
B: The recognition rate was 80% or greater but less than 95%.
C: The recognition rate was 50% or greater but less than 80%.
D: The recognition rate was less than 50%.

Note that, the threshold was set so that white was easily recognized, namely giving a strict judgment. Therefore, “D” or better results are a level that there is no problem in practical use.

### —Prevention of Reduction in Generating Efficiency due to Overflow—

If the adhesive layer is over flown from the connection part between the electrode and the tab wire, generating efficiency may be hindered. Therefore, reduction in generating efficiency due to overflow was evaluated.

The generating efficiency was measured by means of a solar simulator (solar simulator PVS1116i-M, manufactured by Nisshinbo Mechatronics Inc.) in accordance with JIS C8913 (an output measuring method of a crystalline solar battery cell) under the measurement conditions where the illuminance was 1,000 W/m², the temperature was 25° C., and the spectrum was AM 1.5 G.

As for a comparative sample, a solar battery module produced in the same manner as in Example 1, provided that the titanium black was not added in the production of the electrically conductive adhesive film of Example 1, was used.

The generating efficiency (S₀) of the comparative sample, and the generating efficiency (S₁) of the solar battery module that was a measuring sample were measured, and the reduction in the generating efficiency of the measuring sample was measured with the following equation. The results were evaluated based on the following criteria.

Reduction in generating efficiency=S₀−S₁

### [Evaluation Criteria]

A: less than 0.01%
B: 0.01% or greater but less than 0.05%
C: 0.05% or greater but less than 0.10%
D: 0.10% or greater

### —Adhesion—

The peel strength (N/mm) when pealed in 90° direction with tensile strength of 50 cm/min was measured by means of a peel strength tester (Tensilon, manufactured by ORIENTEC CO., LTD.), and evaluated based on the following evaluation criteria.

### [Evaluation Criteria]

A: 2.0 N/mm or greater
B: 1.5 N/mm or greater but less than 2.0 N/mm
C: 1.0 N/mm or greater but less than 1.5 N/mm
D: less than 1.0 N/mm

### —Connection Reliability—

A measuring sample was produced by thermocompression bonding (180° C., 2 MPa, 10 seconds) edges parts (2 mm) of two lines of the tab wire (Cu foil, width: 1.5 mm, thickness: 200 μm) on a glass substrate, on which an Ag electrode (solid electrode) had been formed, with the electrically conductive adhesive film. Note that, the distance between the edge parts of the two lines of the tab wire was 3 mm.

The initial electric resistance of the obtained measuring sample, and the electric resistance thereof after being stored for 500 hours at 85° C., 85% RH were measured by means of a digital multimeter (Digital Multimeter 7555, manufactured by Yokogawa Electric Corporation). The results were evaluated based on the following evaluation criteria.

### [Evaluation Criteria]

A: less than 4 mΩ
B: 4 mΩ or greater but less than 5 mΩ
C: 5 mΩ or greater but less than 6 mΩ
D: 6 mΩ or greater

### Examples 2 to 8

An electrically conductive adhesive film and a solar battery module were produced in the same manner as in Example 1, provided that, in the production of the electrically conductive adhesive film, the amount of Titanium Black 1 and the amount of the electrically conductive particles were changed as depicted in Table 1.

The obtained electrically conductive adhesive film and solar battery module were subjected to the evaluations in the same manner as in Example 1. The results are presented in Table 1.

### Example 9

A solar battery module was produced in the same manner as in Example 1, provided that the electrically conductive adhesive film was changed to the following electrically conductive adhesive film.

The obtained solar battery module was subjected to the evaluations in the same manner as in Example 1. The results are presented in Table 2.

### —Production of Electrically Conductive Adhesive Film—

An electrically conductive adhesive composition was prepared by mixing 20 parts by mass of a phenoxy resin (PKHH, manufactured by InChem), 30 parts by mass of an epoxy resin (jer640, manufactured by Mitsubishi Chemical Corporation, tetrafunctional glycidyl amine type), 15 parts by mass of acrylic rubber (Teisan Resin SGP3, manufactured by Nagase ChemteX Corporation), 15 parts by mass of polybutadiene rubber (RKB series, manufactured by Resinous Kasei Co., Ltd.), 20 parts by mass of an imidazole-based latent curing agent (Novacure HX3941HP, manufactured by Asahi Kasei E-materials Corporation), 5 parts by mass of electrically conductive particles (the silver-coated copper powder produced in the Production Example 1), and 0.1 parts by mass of Titanium Black 1 (13MT, manufactured by Mitsubishi Materials Corporation, average particle diameter: 80 nm).

Next, the obtained electrically conductive adhesive composition was applied on a polyethylene terephthalate film (release film) having a thickness of 50 μm, a surface of which had been subjected to a releasing treatment. The resultant was subjected to a heat treatment in an oven of 80° C. for 5 minutes to form a film. As a result, an electrically conductive adhesive film having the average thickness of 22 μm was obtained.

### Examples 10 to 13

An electrically conductive adhesive film and a solar battery module were produced in the same manner as in Example 9, provided that, in the production of the electrically conductive film, the amount of Titanium Black 1 was changed as depicted in Table 2.

The obtained electrically conductive adhesive film and solar battery module were subjected to the evaluation in the same manner as in Example 1.

### Example 14

An electrically conductive adhesive film and a solar battery module were produced in the same manner as in Example 3, provided that, in the production of the electrically conductive adhesive film, Titanium Black 1 was replaced with Titanium Black 2 (Tilack D, manufactured by AKO KASEI CO., LTD., average particle diameter: 90 nm).

The obtained electrically conductive adhesive film and solar battery module were subjected to the evaluations in the same manner as in Example 1. The results are presented in Table 2.

### Example 15

An electrically conductive adhesive film and a solar battery module were produced in the same manner as in Example 3, provided that, in the production of the electrically conductive adhesive film, the silver-coated copper powder was replaced with nickel powder.

The obtained electrically conductive adhesive film and solar battery module were subjected to the evaluations in the same manner as in Example 1. The results are presented in Table 2.

### Example 16

An electrically conductive adhesive film and a solar battery module were produced in the same manner as in Example 3, provided that, in the production of the electrically conductive adhesive film, the silver-coated copper powder was replaced with copper powder.

The obtained electrically conductive adhesive film and solar battery module were subjected to the evaluations in the same manner as in Example 1. The results are presented in Table 2.

### Comparative Examples 1 to 14

An electrically conductive adhesive film and a solar battery module were produced in the same manner as in Example 1, provided that, in the production of the electrically conductive adhesive film, the type and amount of the colorant, and the type and amount of the electrically conductive particles were changed as depicted in Table 3 or 4.

The obtained electrically conductive adhesive film and solar battery module were subjected to the evaluations in the same manner as in Example 1. The results are presented in Tables 3 and 4.

TABLE 1

| | | | Ex. 1 | Ex. 2 | Ex. 3 | Ex. 4 | Ex. 5 | Ex. 6 | Ex. 7 | Ex. 8 |
|---|---|---|---|---|---|---|---|---|---|---|
| Electrically | Colorant | Type | Titanium | Titanium | Titanium | Titanium | Titanium | Titanium | Titanium | Titanium |
| conductive | | | Black 1 | Black 1 | Black 1 | Black 1 | Black 1 | Black 1 | Black 1 | Black 1 |
| adhesive film | | Amount | 0.1 | 0.3 | 0.5 | 2.0 | 5.0 | 10.0 | 0.5 | 0.5 |
| | | (mass %) | | | | | | | | |
| | Conductive | Type | Silver- | Silver- | Silver- | Silver- | Silver- | Silver- | Silver- | Silver- |
| | particles | | coated | coated | coated | coated | coated | coated | coated | coated |
| | | | copper | copper | copper | copper | copper | copper | copper | copper |
| | | | powder | powder | powder | powder | powder | powder | powder | powder |
| | | Amount | 5 | 5 | 5 | 5 | 5 | 5 | 3 | 10 |
| | | (mass %) | | | | | | | | |

| Storage stability of film | | A | A | A | A | A | A | A | A |
|---|---|---|---|---|---|---|---|---|---|
| Camera recognition | | C | B | A | A | A | A | A | A |
| Prevention of reduction in generating | | A | A | A | A | A | A | A | A |
| efficiency due to overflow | | | | | | | | | |
| Adhesion | | A | A | A | A | A | A | A | A |
| Connection | Initial | A | A | A | A | A | A | A | A |
| reliability | 85° C., 85% RH, for | A | A | A | A | A | B | B | B |
| | 500 hours | | | | | | | | |

TABLE 2

| | | | Ex. 9 | Ex. 10 | Ex. 11 | Ex. 12 | Ex. 13 | Ex. 14 | Ex. 15 | Ex. 16 |
|---|---|---|---|---|---|---|---|---|---|---|
| Electrically | Colorant | Type | Titanium | Titanium | Titanium | Titanium | Titanium | Titanium | Titanium | Titanium |
| conductive | | | Black 1 | Black 1 | Black 1 | Black 1 | Black 1 | Black 2 | Black 1 | Black 1 |
| adhesive film | | Amount | 0.1 | 0.3 | 0.5 | 2.0 | 5.0 | 0.5 | 0.5 | 0.5 |
| | | (mass %) | | | | | | | | |
| | Conductive | Type | Silver- | Silver- | Silver- | Silver- | Silver- | Silver- | Ni | Copper |
| | particles | | coated | coated | coated | coated | coated | coated | | powder |
| | | | copper | copper | copper | copper | copper | copper | | |
| | | | powder | powder | powder | powder | powder | powder | | |
| | | Amount | 5 | 5 | 5 | 5 | 5 | 5 | 5 | 5 |
| | | (mass %) | | | | | | | | |

| Storage stability of film | | A | A | A | A | A | A | A | A |
|---|---|---|---|---|---|---|---|---|---|
| Camera recognition | | C | B | A | A | A | A | A | A |
| Prevention of reduction in generating | | A | A | A | A | A | A | C | A |
| efficiency due to overflow | | | | | | | | | |
| Adhesion | | A | A | A | A | A | A | A | A |
| Connection | Initial | A | A | A | A | A | A | C | B |
| reliability | 85° C., 85% RH, for | A | A | A | A | A | A | C | C |
| | 500 hours | | | | | | | | |

TABLE 3

| | | | Comp. | Comp. | Comp. | Comp. | Comp. | Comp. | Comp. | Comp. |
|---|---|---|---|---|---|---|---|---|---|---|
| | | | Ex. 1 | Ex. 2 | Ex. 3 | Ex. 4 | Ex. 5 | Ex. 6 | Ex. 7 | Ex. 8 |
| Electrically | Colorant | Type | Carbon | Carbon | Carbon | — | — | — | Dye | Organic |
| conductive | | | Black 1 | Black 1 | Black 1 | | | | | pigment |
| adhesive film | | Amount | 0.1 | 0.5 | 5.0 | — | — | — | 0.5 | 0.5 |
| | | (mass %) | | | | | | | | |
| | Conductive | Type | Silver- | Silver- | Silver- | Ni | Ni | Copper | Silver- | Silver- |
| | particles | | coated | coated | coated | | | powder | coated | coated |
| | | | copper | copper | copper | | | | copper | copper |
| | | | powder | powder | powder | | | | powder | powder |
| | | Amount | 5 | 5 | 5 | 5 | 15 | 5 | 5 | 5 |
| | | (mass %) | | | | | | | | |

| Storage stability of film | | D | D | D | A | A | B | A | D |
|---|---|---|---|---|---|---|---|---|---|
| Camera recognition | | A | A | A | C | A | C | D | D |
| Prevention of reduction in generating | | D | D | D | C | D | C | B | C |
| efficiency due to overflow | | | | | | | | | |
| Adhesion | | D | D | D | A | A | C | A | C |
| Connection | Initial | D | D | D | C | B | C | B | C |
| reliability | 85° C., 85% RH, for | D | D | D | D | C | C | C | D |
| | 500 hours | | | | | | | | |

TABLE 4

| | | | Comp. | Comp. | Comp. | Comp. | Comp. | Comp. |
|---|---|---|---|---|---|---|---|---|
| | | | Ex. 9 | Ex. 10 | Ex. 11 | Ex. 12 | Ex. 13 | Ex. 14 |
| Electrically | Colorant | Type | Titanium | Titanium | — | Carbon | Carbon | Titanium |
| conductive | | | dioxide | dioxide | | Black 2 | Black 3 | Black 1/ |
| adhesive film | | | | | | | | Carbon |
| | | | | | | | | Black 1 |
| | | Amount | 0.5 | 5.0 | — | 0.5 | 0.5 | 0.4/0.1 |
| | | (mass %) | | | | | | |
| | Conductive | Type | Silver- | Silver- | Silver- | Silver- | Silver- | Silver- |
| | particles | | coated | coated | coated | coated | coated | coated |
| | | | copper | copper | copper | copper | copper | copper |
| | | | powder | powder | powder | powder | powder | powder |
| | | Amount | 5 | 5 | 5 | 6 | 5 | 5 |
| | | (mass %) | | | | | | |

| Storage stability of film | | A | A | A | D | D | D |
|---|---|---|---|---|---|---|---|
| Camera recognition | | D | D | D | A | A | A |
| Prevention of reduction in generating | | C | | A | D | D | D |
| efficiency due to overflow | | | | | | | |
| Adhesion | | A | A | A | D | D | D |
| Connection | Initial | B | B | A | D | D | D |
| reliability | 85° C., 85% RH, for | B | B | A | D | D | D |
| | 500 hours | | | | | | |

In Tables 1 to 4, the amount of the colorant, and the amount of the electrically conductive particles were each an amount (% by mass) relative to 100 parts by mass of the resin (including the film forming resin, heat curable resin, rubber, copolymer, curing agent, etc.) in the electrically conductive adhesive film

The colorants and electrically conductive particles depicted in Tables 1 to 4 are as follows.

Titanium Black 2: Tilack D, manufactured by AKO KASEI CO., LTD., average particle diameter: 90 nm
Carbon Black 1: #3050B, manufactured by Mitsubishi Chemical Corporation, average particle diameter: 50 nm
Carbon Black 2: Denka Black, manufactured by DENKI KAGAKU KOGYO KABUSHIKI KAISHA, acetylene black, average particle diameter: 35 nm
Carbon Black 3: Ketjenblack EC600JD, manufactured by Lion Corporation, ketjen black, average particle diameter: 34 nm
Ni: HCA-1, manufactured by INCO LIMITED, nickel powder, average particle diameter: 10 μm
Copper Powder: T-220, manufactured by MITSUI MINING & SMELTING CO., LTD., average particle diameter: 10 μm
Dye: Sumiplast Blue S, manufactured by Sumika Chemtex Company, Limited.
Organic Pigment: CYANINE BLUE KRO, manufactured by SANYO COLOR WORKS, Ltd.
Titanium Dioxide: FTR700, manufactured by SAKAI CHEMICAL INDUSTRY CO., LTD., average particle diameter: 200 nm

In Examples 1 to 16, the excellent results could be attained in all of the storage stability of the film, recognition by cameras, prevention of reduction in generating efficiency due to overflow, adhesion, and connection reliability.

Especially in the case where the amount of the titanium black was 0.3% by mass to 10.0% by mass, excellent results could be attained in all of the storage stability of the film, recognition by cameras, prevention of reduction in generating efficiency due to overflow, adhesion, and connection reliability. In the case where the amount thereof was 0.5% by mass to 5.0% by mass, extremely excellent results could be attained (see Example 1 to 6).

In the case where the amount of the silver-coated copper powder was 3% by mass to 10% by mass, excellent results are attained in all of the storage stability of the film, recognition by cameras, prevention of reduction in generating efficiency due to overflow, adhesion, and connection reliability. (see Examples 3, 7, and 8).

In both of the case where the acrylate resin was used as the curable resin (see, for example, Examples 1 to 6), and the case where the epoxy resin was used as the curable resin (see Examples 9 to 13), excellent results were attained.

In the case where the titanium black was changed from 13MT manufactured by Mitsubishi Materials Corporation to Tilack D manufactured by AKO KASEI CO., LTD., there was no difference in the results, and the excellent results were attained (see Example 14).

In the case where the silver-coated copper powder was used as the electrically conductive particles (for example, Example 3), connection reliability was extremely excellent compared to the case where nickel powder or copper powder was used as the electrically conductive particles (see Examples 15 and 16).

In Comparative Examples 1 to 3, 12, and 13 where the colorant was changed from the titanium black to the carbon black, all of the storage stability of the film, prevention of reduction in generating efficiency due to over flow, adhesion, and connection reliability were unsatisfactory compared to the results of Examples.

In Comparative Example 4 where the titanium black was not added, and nickel powder was used as the electrically conductive particles, the recognition by cameras was low. In Comparative Example 5 where the amount of the nickel powder was increased from Comparative Example 4, moreover, the recognition by cameras, and the connection reliability were improved, but the prevention of reduction in generating efficiency due to overflow was insufficient, and all of the storage stability of the film, recognition by cameras, prevention of reduction in generating efficiency due to overflow, adhesion, and connection reliability were not satisfactory.

In Comparative Example 6 where the colorant was not contained, and the copper powder was used as the electrically conductive particles, Comparative Example 7 where the blue dye was used as the colorant, Comparative Example 8 where the blue pigment was used as the colorant, Comparative Examples 9 and 10 where the white pigment was used as the colorant, and Comparative Example 11 where the colorant was not contained, all of the storage stability of the film, recognition by cameras, prevention of reduction in generating efficiency due to overflow, adhesion, and connection reliability were not also satisfactory.

Even in the case where the titanium black was used as the colorant but carbon black was used in combination (Comparative Example 14), the prevention of reduction in generating efficiency due to overflow, adhesion, and connection reliability were insufficient.

The electrically conductive adhesive of the present invention has excellent recognition by cameras, adhesion, and connection reliability, has storage stability, and does not adversely affect generating efficiency, and therefore the electrically conductive adhesive of the present invention can be suitably used as an electrically conductive adhesive for use in a solar battery module. Moreover, the method for producing a solar battery module according to the present invention can produce with fewer steps, and therefore the method is suitably used for production of the solar battery module of the present invention.

What is claimed is:

1. An electrically conductive adhesive, comprising:
a curable resin;
electrically conductive particles;
a curing agent; and
a black colorant consisting of titanium black,
wherein the electrically conductive particles are silver-coated copper powder, and
wherein the electrically conductive adhesive is configured to connect an electrode of a solar battery cell with tab wire.

2. The electrically conductive adhesive according to claim 1, wherein an amount of the black colorant consisting of the titanium black is 0.1% by mass to 10.0% by mass relative to resins in the electrically conductive adhesive.

3. The electrically conductive adhesive according to claim 1, wherein an amount of the electrically conductive particles is 3% by mass to 10% by mass relative to resins contained in the electrically conductive adhesive.

4. The electrically conductive adhesive according to claim 1, wherein the electrically conductive adhesive is in the form of a film, or a paste.

5. The electrically conductive adhesive according to claim 1, wherein the electrically conductive adhesive is in the form of a film, or a paste, wherein the electrically conductive particles are silver-coated copper powder, and wherein an amount of the electrically conductive particles is 3% by mass to 10% by mass relative to resins in the electrically conductive adhesive.

6. A solar battery module, comprising:
a solar battery cell containing an electrode;
tab wire; and
an adhesive layer,
wherein the electrode of the solar battery cell is connected to the tab wire through the adhesive layer,
wherein the adhesive layer is formed of an electrically conductive adhesive, and
wherein the electrically conductive adhesive contains a curable resin, electrically conductive particles, a curing agent, and a black colorant consisting of titanium black, where the electrically conductive particles is silver-coated copper powder.

7. The solar battery module according to claim 6, wherein an amount of the black colorant consisting of the titanium black in the electrically conductive adhesive is 0.1% by mass to 10.0% by mass relative to resins in the electrically conductive adhesive.

8. The solar battery module according to claim 6, wherein an amount of the electrically conductive particles in the electrically conductive adhesive is 3% by mass to 10% by mass relative to resins in the electrically conductive adhesive.

9. The solar battery module according to claim 6, wherein the electrically conductive adhesive is in the form of a film or a paste.

10. The solar battery module according to claim 6, wherein the electrically conductive adhesive is in the form of a film or a paste, the electrically conductive particles are silver-coated copper powder, and an amount of the electrically conductive particles is 3% by mass to 10% by mass relative to resins in the electrically conductive adhesive.

11. A method for producing a solar battery module, comprising:
arranging an adhesive layer formed of an electrically conductive adhesive and tab wire on an electrode of a solar battery cell that contains the electrode so that the electrode and the tab wire are bonded via the adhesive layer and are electrically connected as pressed and heated;
covering the solar battery cell with a sealing resin, and further covering the sealing resin with a moisture-proof backing sheet or a glass plate;
pressing either the moisture-proof backing sheet or the glass plate; and
heating a heating stage on which the solar battery cell is placed,
wherein the electrically conductive adhesive contains a curable resin, electrically conductive particles, a curing agent, and a black colorant consisting of titanium black, and
wherein the electrically conductive particles are silver-coated copper powder.

12. The method according to claim 11, wherein an amount of the black colorant consisting of the titanium black in the electrically conductive adhesive is 0.1% by mass to 10.0% by mass relative to resins in the electrically conductive adhesive.

13. The method according to claim 11, wherein an amount of the electrically conductive particles in the electrically conductive adhesive is 3% by mass to 10% by mass relative to resins in the electrically conductive adhesive.

14. The method according to claim 11, wherein the electrically conductive adhesive is in the form of a film or a paste.

15. The method according to claim 11, wherein the electrically conductive adhesive is in the form of a film or a paste, the electrically conductive particles are silver-coated copper powder, and an amount of the electrically conductive particles is 3% by mass to 10% by mass relative to resins in the electrically conductive adhesive.
